(19) United States
(12) Patent Application Publication
(10) Pub. No.: US 2010/0321148 A1
(43) Pub. Date: Dec. 23, 2010

(54) WIRELESS INTELLIGENT SOLAR POWER READER (WISPR) STRUCTURE AND PROCESS

(76) Inventor: Peter Gevorkian, La Canada, CA (US)

Correspondence Address: PILLSBURY WINTHROP SHAW PITTMAN LLP, P.O BOX 10500, McLean, VA, 22102, US

(21) Appl. No.: 12/487,564

(22) Filed: Jun. 18, 2009

(51) Int. Cl. G05B 23/02; H01L 31/042

(52) U.S. Cl. 340/3.1; 136/244

(57) ABSTRACT

A computer-implemented method of operating a wireless intelligent solar power reader (WISPR) module includes receiving a command from an external device, the command requesting an output power reading from a photovoltaic (PV) module and transmitting the output power request to the photovoltaic module. The WISPR Module receives the output power reading from the photovoltaic module and transmits the output power reading to the external device. In an embodiment of the invention, the command also requests meteorological information from a weather instrument located in proximity to the WISPR module and the WISPR modules transmit the meteorological request to the weather instrument. The WISPR module receives the meteorological reading from the weather instrument and transmits the meteorological reading to the external device.

### BACKGROUND OF THE INVENTION

Solar panels are now being utilized in commercial and residential installations to provide operating power. As with any electrical power system, safety is of paramount importance for a solar power system.

The shock hazard control and suppression from an active solar power system is of paramount important to fire fighting personnel's safety for roof mounted solar power installations during fire fighting conditions. An intervention with a roof mounted solar power system during daylight hours, (such as breaking a portion of the solar panel array to penetrate the roof to gain access to the fire with water), exposes firefighters to a very high voltage DC power, e.g., 600 volts DC power, that could result in serious life safety and potentially a lethal hazard condition. Similar conditions can occur during natural disasters such as earthquake or floods where emergency personnel or building inhabitants may come in contact with the solar power system.

Accordingly, there is a need for a solar power system that automatically shuts off a solar panel during times of emergency or maintenance. A solar power system also needs the capability of selectively shutting down or deactivating single photovoltaic (PV) modules or a group of PV modules.

### BRIEF DESCRIPTION OF THE DRAWINGS

FIG. 1a illustrates a photovoltaic string and corresponding WISPR modules according to an embodiment of the invention;

FIG. 1b illustrates the interconnection of a WISPR module to a PV junction box according to an embodiment of the invention;

FIG. 2 illustrates a WISPR module according to an embodiment of the invention;

FIG. 3 illustrates a solar power system according to an embodiment of the invention;

FIG. 4a illustrates a handheld terminal communicating with a DACS system according to an embodiment of the invention; and

FIG. 4b is a flowchart illustrating operation of the DACS system and wireless communication modules according to an embodiment of the invention.

### SUMMARY OF THE INVENTION

A high voltage of 600 volts DC and 10 amps current may be present at the output of a typical solar power string or solar power array. Individual solar PV arrays may present a dangerous life safety hazard during emergency or hazardous conditions. A Wireless Intelligent Solar Power Reader (WISPR) may be coupled to each photovoltaic (PV) module in a solar power system. One of the significant features of the Wireless Intelligent Solar Power Reader (WISPR) device is the ability to provide safe deactivation of the solar power system to prevent shock hazard resulting from active solar power systems. A Data Acquisition and Control System (DACS) may also deactivate a WISPR module, a group of WISPR modules, or all of the WISPR modules.

The WISPR modules along with a plurality of photovoltaic modules, at least one DC combiner, an inverter, at least one short range wireless radio, a WAN Gateway, and the DACS form a solar power system. The WISPR modules, in addition to the above-identified safety functionality, may provide optional remote control scheduled and real-time addressable security power shutdown and activation for individual photovoltaic (PV) modules within the solar power system. This is in addition to system wide shutdown or activation of all PV modules.

The solar power system with the DACS also provides real-time reporting capabilities (or as needed reporting capabilities) of the output power of the PV modules as well as meteorological readings corresponding to the environment where the PV modules are installed.

### DETAILED DESCRIPTION OF THE INVENTION

A large number of solar panels may provide grid like power for buildings or other large installations. This may be referred to as a solar power farm. The solar farm may be a very large solar power installation where thousands of photovoltaic (PV) panels (or modules) are used to provide Grid type (e.g., very large current) power.

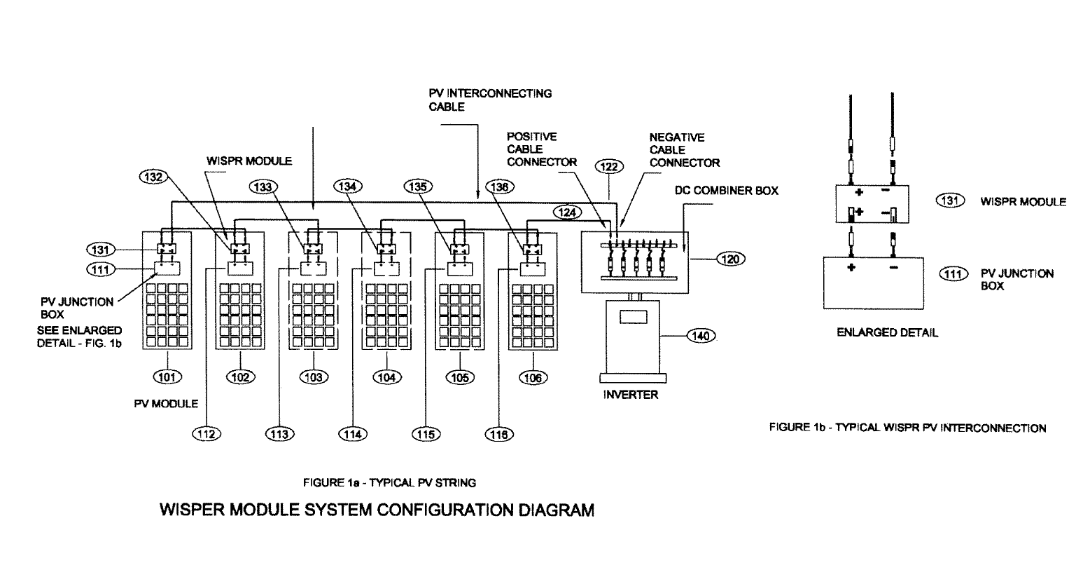

FIG. 1a illustrates a photovoltaic string and corresponding WISPR modules according to an embodiment of the invention. A PV module (or panel) includes a solar cell and electronics to generate a voltage and a current after receiving rays or light from a solar power source (e.g., the sun). The PV module may be connected in series with a number of other PV modules. In an embodiment of the invention, the PV module may be connected in parallel with other PV modules. The connecting of PV modules in series is similar to tandem connected batteries which are connected in series. A PV module produces power only when the PV module is exposed to a solar ray. If the PV modules are connected in series, the power output of the PV modules that are connected in series is proportional to the number of connected PV modules. A plurality of series connected PV modules may be referred to as a PV string or a PV module string. Illustratively, a PV string may include 9 or 12 series connected PV modules.

FIG. 1a includes PV Modules 101, 102, 103, 104, 105, 106. Each of the PV modules includes a PV Junction box 111, 112, 113, 114, 115 and 116. The PV junction box allows the series connection of the PV modules to one another and then to a DC Combiner Box 120. In FIG. 1a, the DC combiner box 120 includes a negative cable connector 122 coupled to the PV module 101 and thus the PV junction box 111 and also a positive cable connector 124 coupled to the last PV module 106 and then the PV junction box 116. More specifically, the negative cable connector 122 and the positive cable connector 124 are connected to WISPR modules within the PV modules.

FIG. 1b illustrates the interconnection of a WISPR module 131 to a PV junction box 111. As is illustrated in FIG. 1b, the WISPR module is positioned between the cable connector (e.g., cable connector 122) and the PV junction box 111. In other words, the WISPR module 131 sits between the PV module and a connection to the outside devices (e.g., DC combiner box 120 or other PV modules). In an embodiment of the invention, the WISPR module may be located within the same physical apparatus as the PV module. In an embodiment of the invention, the WISPR module may be attached or coupled to the PV module. In an embodiment of the invention, each of the PV modules 101, 102, 103, 104, 105 and 106, has a corresponding WISPR module (e.g., WISPR modules 131, 132, 133, 134, 135 and 136).

In an embodiment of the invention, a plurality of PV modules which form a PV module string (PV String) produce a current (I) and a voltage (V). Each of the PV modules in the PV String together constitute a measure of the generated DC power. DC power produced by the PV string may be converted to AC power by a power inverter 140, as is illustrated in FIG. 1a. In an embodiment of the invention, an inverter 140 may accept a plurality of PV strings. For example, the number of PV strings an inverter accepts may range from 4 PV strings to 126 PV strings. In an embodiment of the invention, each of the PV strings may have a DC combiner box 120 that receives the output power from the PV modules in the PV string and then inputs that power to the inverter 140. Illustratively, FIG. 1a is a PV string including 6 PV modules.

A solar array may consist of a group of PV strings, e.g., 20 PV strings, 30 PV strings, or 50 PV strings, that are connected to an inverter. A solar subarray is a group of PV strings within a solar array. For example, a solar array may include 20 PV strings where the 20 PV strings are divided into 4 subarrays of 5 PV strings each.

A large group of solar arrays forms a solar power system. A solar farm may be used to describe a very large number of solar power systems that are installed in a large geographic area, e.g., multiple acres of land.

As discussed above, in an embodiment of the invention, a WISPR module is coupled or attached to each solar PV module and is directly connected to the PV junction box. The WISPR module (e.g., 131) reads a power output from each solar PV module (e.g., 101). In other words, the WISPR module measures a voltage reading and a current reading from each solar PV module. Each WISPR module transmits the measured output power information (e.g., measured voltage and current) to an external device. Accordingly, in a solar farm, there may be thousands of PV modules and a corresponding number of WISPR modules either attached to or coupled to each of the thousands of PV units.

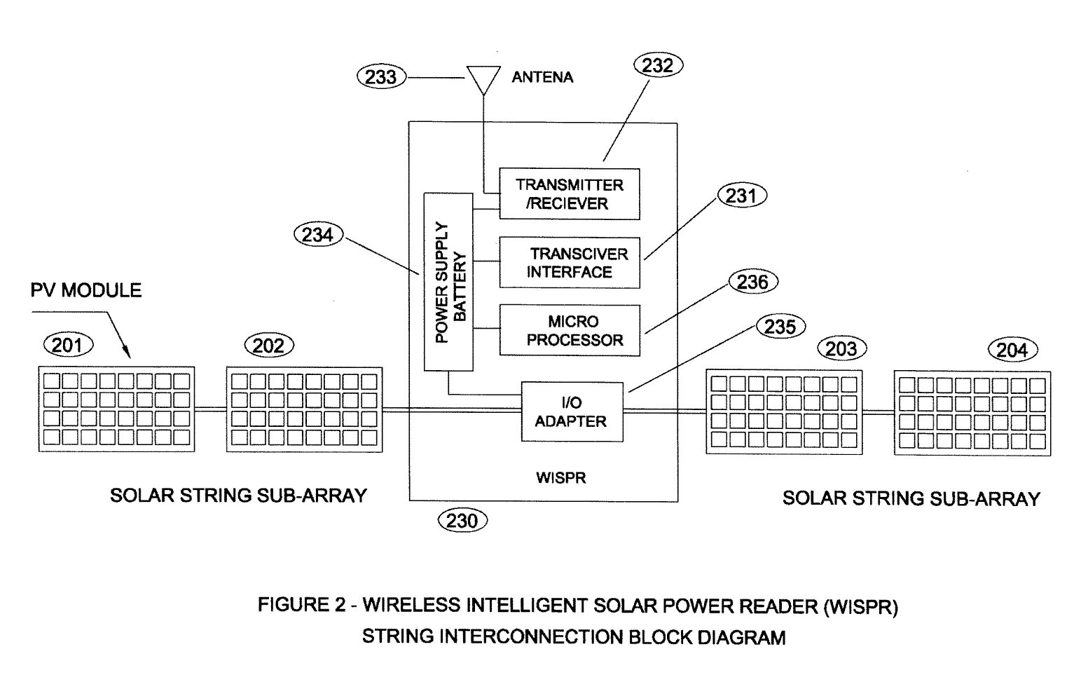

FIG. 2 illustrates a WISPR module according to an embodiment of the invention. The WISPR module 230 includes a transceiver 232, a transceiver interface 231, an antenna 233, a power supply module 234, a microprocessor/microcontroller 236 and an I/O adapter 235. The transceiver 232 is coupled to the antenna 233 and also the transceiver interface 231. The microprocessor 236 is coupled to the transceiver interface 231 and also the I/O adapter 235. The power supply module 234 provides power (and is thus coupled to) the transceiver 232, the transmitter interface 231, the microprocessor 236 and the I/O adpater 235. FIG. 2 also illustrates a WISPR module 230 coupled to PV modules 201, 202, 203 and 204. WISPR modules 201, 202, 203 and 204 may form a PV string subarray.

As illustrated in FIG. 2, each WISPR module 230 includes an embedded radio communication device (e.g., the transceiver and antenna) that transmits data to an external device and receives information data back from an external device. The external device may be the Data Acquisition and Control System (DACS). Software located on the WISPR module (e.g., within the microcontroller or within a memory in the WISPR module) controls the communication to and from the DACS. The WISPR module 230 (the transmitter and antenna) may transmit power output information and atmospheric and/or meteorological data to the external device. The WISPR module 230 may receive control or operating commands from the external device.

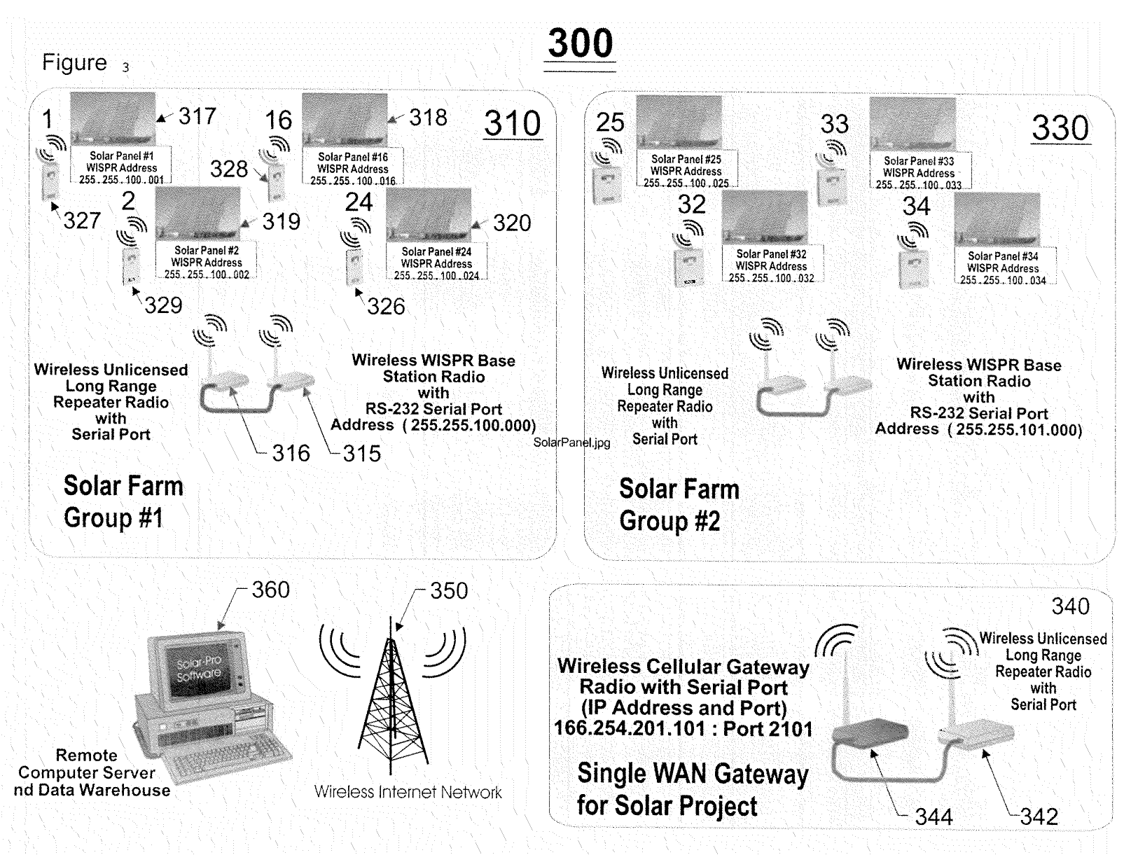

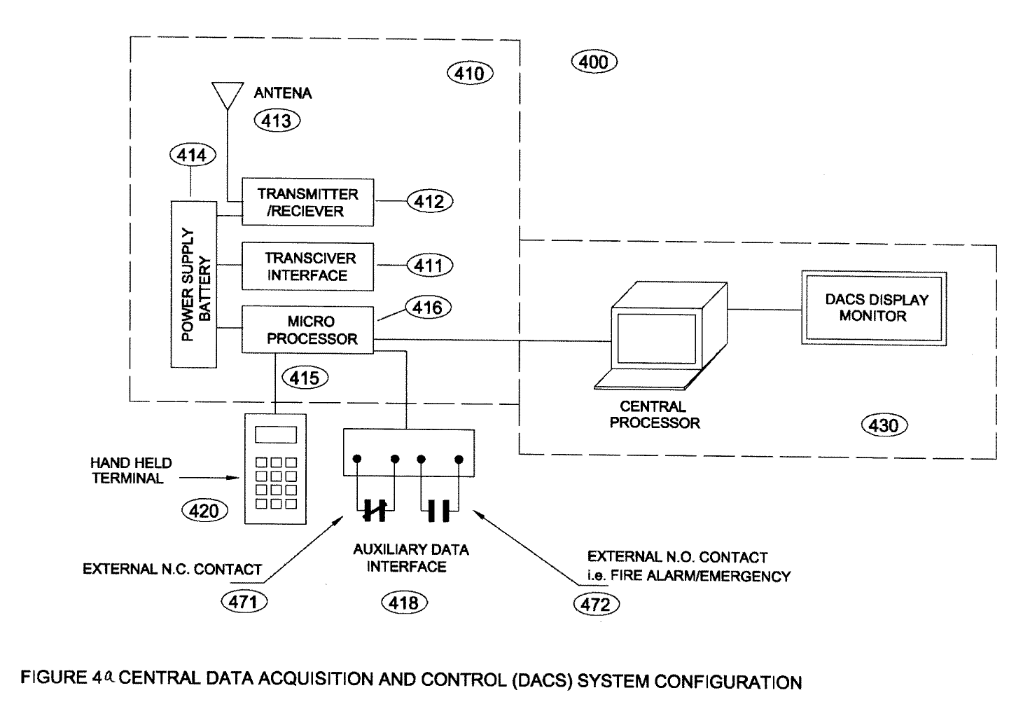

FIG. 3 illustrates a solar power system according to an embodiment of the invention. FIG. 3 illustrates a solar power system 300 with a plurality of solar farms 310 and 330, a WAN Gateway 340, a wireless internet network 350 and a data acquisition and control system (DACS) 360. Although only two solar farms (310 and 330) are illustrated, additional solar farms may be part of the solar power system. The solar farm 310 may include a base station radio 315. The base station radio 315 may include a RS-232 serial port. The base station radio 315 may have an assigned IP address. The solar farm 310 may also include a wireless repeater radio 316. The wireless repeater radio 316 may also include a serial port. In FIG. 3, four solar panels 317, 318, 319 and 320 are illustrated. This is for illustrative purposes only and more than four solar panels may be present in the solar farm. Only four solar panels are illustrated to simplify the drawing.

Four WISPR modules are shown, e.g., WISPR modules 326, 327, 328 and 329. FIG. 3 is not meant to identify that the invention is limited to one WISPR module per solar panel. In embodiments of the invention, such as is illustrated in FIG. 3, each PV module has a corresponding WISPR module. The illustration of only four WISPR modules 326, 327, 328 and 329 is meant to simplify the description and more than four WISPR modules may be present in the solar farm. In FIG. 3, each illustrated WISPR module has a unique IP address to allow communications specifically to the transceiver of the identified WISPR module. For example, WISPR module 326 has an IP address of 255.255.100.001. In an embodiment of the invention, a WISPR module communicates (or transmits) information wirelessly to the corresponding base station radio 315. The base station radio 315, depending on the identified communication recipient, may transmit the information from the WISPR module to 1) another WISPR module 327 within the same solar farm; 2) another WISPR module within a different solar farm (e.g., solar farm 330) or 3) to the WAN Gateway 350. In addition, the WISPR module may communicate with other WISPR modules within its own solar farm utilizing localized wireless communications technology, e.g., Bluetooth, wireless local area networking communication protocols. The base station radio 315 may utilize the wireless repeater radio 316 to strengthen the data transmission.

In an embodiment of the invention, the WAN Gateway 340 is utilized to transmit information received from WISPR modules to a remote DACS system 360 via a wireless cellular network 350. The WAN Gateway 340 has its own IP address to receive communications from both the WISPR modules and the DACS system 360. The WAN Gateway 340 may include a Gateway radio (with a serial port) 342 and also a wireless long range repeater radio 344 (with a serial port) to increase a transmission strength. The DACS system 360 has a capability of communicating with each WISPR module separately (through the WISPR module's IP address), a subset of the WISPR modules (by addressing multiple WISPR module's IP addresses) or all of the WISPR modules within the solar power system.

As identified above, WISPR modules may communicate with each other (i.e., not including the DACS system) utilizing the transceiver that is part of the WISPR module. Illustratively, each WISPR module could communicate with each other utilizing an on-board frequency hopping spread spectrum transceiver and identifying the other WISPR module's IP address.

FIG. 3 illustrates only one methodology of communication between the WISPR modules and the DACS system. Communication may also occur via other WAN gateways utilizing technologies such as cellular modems, satellite communications, POTS dial up modems, power line carrier and land line communications. Protocols which may be used to communicate between the WISPR modules and the DACS system include the USB protocol, the RS232 protocol, the RS485 protocol and the Ethernet protocol.

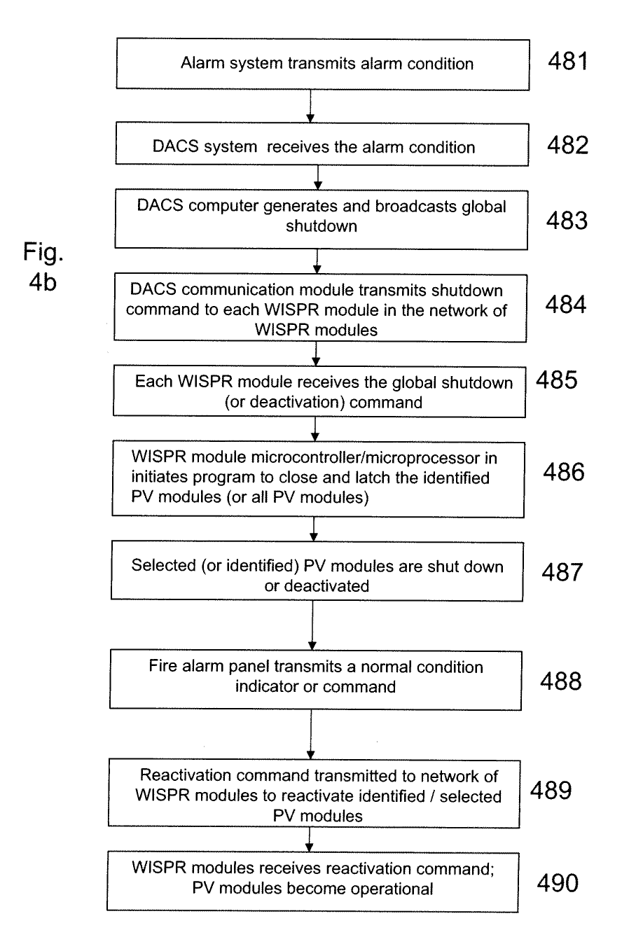

FIG. 4a illustrates a handheld terminal communicating with a DACS system according to an embodiment of the invention. FIG. 4a illustrates a handheld terminal 420 and a DACS system 430. The DACS system includes a communication module and the communication module 410 includes a transceiver 412, an antenna 413, the transceiver interface 411, a microprocessor 416, a second interface 415 and the power supply module 414.

In the embodiment of the invention illustrated in FIG. 4a, the handheld terminal 420 can communicate directly with the DACS communication module 410. As is illustrated in FIG. 4, the handheld terminal 420 may be directly connected to the DACS communication module 410 via the second interface 415. The handheld terminal 420 may also be coupled to the DACS communication module 410 via wireless link so that the handheld terminal 420 communicates wirelessly with the DACS communication module 410.

The handheld terminal 420 utilizes the communication module 410 to communicate with the DACS computer 430. Illustratively, if a firefighter had a handheld terminal 420, the firefighter could couple or connect to the communications module 410 and communicate to the DACS computer 430 to have the DACS computer 430 initiate a command that results in all PV modules being shut down. The DACS computer 430 generates the command and transmits the command utilizing the communication module 410 (e.g., the transmitter 412 and antenna 413).

In an embodiment of the invention, the handheld terminal 420 may also include a transceiver (e.g., like the WISPR modules utilize) and may be able to directly communicate with all other WISPR modules as well as the DACS system. In an embodiment of the invention, the handheld terminal 420 itself could issue a shut down command that is communicated to all of the PV modules via the WISPR modules.

In an embodiment of the invention, the DACS system also includes an auxiliary interface 418. In an embodiment of the solar power system for a residential or commercial building, a DACS communication module 410 may be interlocked with a central or a local fire alarm control system. This interlocking may occur utilizing an auxiliary interface 418 which may be an open or closed contact (and is referred to as NO/NC). The auxiliary interface is illustrated in FIG. 4a and includes an external N/C contact 471 and an external N/O contact 472. The external N/O contact 472 is interfaced with a hazard alarm system, e.g., a fire alarm panel. The fire alarm panel (within the building) may initiate, through the external N/O contact 472, the DACS system to shutdown the solar power system. FIG. 4b is a flowchart illustrating operation of the DACS system and wireless communication modules according to an embodiment of the invention. The fire alarm may transmit a fire alarm condition 481. The solar power system may also be set up so that any type of hazard detection system (e.g., earthquake, flooding, etc.) may be interlocked with the DACS system. The DACS system (e.g., the DACS communication module 410) receives 482 the fire alarm condition (or other hazard condition). In an embodiment of the invention, the auxiliary interface 418 receives the alarm condition and communicates with the microprocessor 416 in the communication module 410. The microprocessor 410 communicates the alarm condition to the central processor in the DACS computer 430. The DACS computer generates 483 a broadcast global shutdown command that is to be sent to the network of WISPR modules within the solar power system. The broadcast global shutdown command is sent from the DACS computer 430 to the DACS communication module 410 and is transmitted 484 from the DACS communication module to each WISPR module in the network of WISPR modules. Each WISPR module receives 485 the global shutdown (or deactivation) command. The microcontroller or microprocessor in each WISPR module initiates 486 a computer program to close and latch the PV module. The initiation of the computer program in the WISPR modules results in all of the PV modules being shut down 487 simultaneously or almost simultaneously. After the fire condition (or the other hazard condition) is mitigated, the solar power system may return to active service by the fire alarm panel sending 488 a normal condition (or returning to a normal state). After the DACS computer receives the normal condition command (through the auxiliary interface and communication module microprocessor), the DACS computer 430 issues 489 a broadcast command (through the DACS communication module 410) to each of the WISPR modules to reactivate the PV modules. The WISPR modules receives the reactivation command and this results in the PV modules being opened 490 and becoming operational. The DACS system (e.g., the DACS communication module 410 and DACS computer 430) may also communicate and transfer shutdown and reactivation commands to a selected group of WISPR modules or a single WISPR module.

In an embodiment of the invention, the reception of the global deactivation command at each of the WISPR modules initiates a program within each WISPR module to close and latch a relay (e.g., the relay is rated at 600 volts DC and 10 Amps). This results in the shorting or crow-barring of the output of each photovoltaic (PV) module.

The DACS system may initiate scheduled panel deactivation and reactivation instructions. The scheduled shutdowns and/or activations of the solar PV panels may be initiated by the DACS system for a single PV module, a string of PV modules or for the entire system power system of PV modules. For example, every month maintenance may need to be performed on specific PV modules and the DACS system (e.g., the DACS computer) may include software that initiates the scheduled deactivation and reactivation of the specific PV modules. The schedule shutdowns may be implemented at each of the WISPR modules by means of an on-board relay with a dry contact that shorts and eliminates the output power at each solar PV panel. In an embodiment of the invention, the relay is on the WISPR module.

The solar power system may also utilize the WISPR modules to provide power output status and other operational information for each of the WISPR modules. As discussed above, the DACS system 400 may receive or initiate communication with each WISPR module. The DACS system, as identified above, includes a DACS communication module 410 and a DACS computer 430. The DACS computer 430 may be either a local computer (i.e., a computer in a building with the solar power system) or a remote computer (in a different location from the solar power system). The DACS computer itself may be a desktop or laptop computer. The DACS computer 430 may include a database program, a DACS application program, a processor, a communication interface, volatile memory and non-volatile memory. A DACS software application may be stored in the non-volatile memory. The DACS software application includes commands, when executed by a processor in the DACS computer, that cause the DACS computer 430 and DACS communication module 410 to monitor and control a plurality of WISPR modules, or to monitor and control individual WISPR module. The DACS system also may include a modem.

In an embodiment of the invention, the DACS communication module may also include a hardware I/O device (e.g., interface box) designed to transmit and receive digital and analog signals. In an embodiment of the invention, the hardware I/O device or interface box allows for adding of expansion and future capabilities.

The DACS computer 430 may also include a display and a printer. Once initiated, the DACS application software, which is installed on the non-volatile memory, has instructions which are executed by the processor (or controller). The DACS communication module 410 may also include a transceiver, antenna, transceiver interface, controller and power supply module. The DACS communication module 410 may receive information from the WISPR modules or transmit information to the WISPR modules.

The processor utilizes the volatile memory to execute programs. The DACS system, upon reception at the transceiver of the measured parameters (e.g., output power and meteorological/atmospheric conditions) from each WISPR module, may store the measured parameters within a database residing on the non-volatile memory in the DACS computer 430. The DACS computer 430, under certain operating conditions, may also store the measured parameters temporary in files in the volatile memory. The DACS application software utilizes the received parameters (or measurements) and, along with the processor, performs statistical calculations. The results of the statistical calculations may be stored in the database (or in temporary files in the volatile memory). The results of the statistical calculations may also be presented in reports. These reports may have tabular or graphical formats and may be visually displayed on a monitor (or display) or may be printed out on a hard copy (e.g., a printer). The reports and the information utilized to create the reports may also be stored in the database for historical purposes.

The DACS system may be programmed to interface with (and communicate with) a number of solar power systems. Illustratively, a DACS system located in one physical location may control a plurality of (e.g., five) solar power systems that are located in five different commercial properties. In order to interface with (and communicate with) the plurality of solar power systems and the WISPR modules installed in the plurality of solar power systems, the database in the DACS system has to be programmed with addresses (e.g., IP addresses) for each of the WISPR modules that are to controlled (and thus communicated with) in each of the solar power systems. Accordingly, for each WISPR module (and corresponding PV module) the DACS system communicates with, a database in the DACS computer 430 has to include addresses (e.g., IP addresses) that identify the WISPR modules.

The DACS system (e.g., the DACS communication module) may communicate data to and from the WISPR modules via a WAN gateway to a single WISPR module's transceiver and antenna. The DACS communication module may also provide data encoding/decoding, data formatting, and data security checking for all messages transmitted by and received by the DACS. The DACS system (e.g., the DACS computer) may also include address activation and address deactivation for recently installed or recently removed WISPR modules.

The DACS system may also provide an external I/O hardware interface to monitor and detect auxiliary hard contact inputs from fire alarm systems (or other hazard systems). As disclosed above, the DACS system may transmit commands to turn on and off the shunting (or crowbarring) relay on each individual WISPR module (e.g., for maintenance purposes) or to broadcast a global command to shut down all WISPR modules and corresponding PV modules (for fire alarms or emergency situations such as an earthquake). In an embodiment of the invention, the DACS system may transmit sequential data acquisition commands to monitor individual PV module performance on a polled basis. For example, these commands may be polled at a set time interval to each of the individual PV modules.

In an embodiment of the invention, the DACS system (e.g., communication module) may communicate with the WISPR modules in a protocol utilizing a serial data packet configuration. Below is a brief description of the communication protocol format. This data protocol was developed by Winn Energy.

### Handshake Protocol—Transmitted by DACS Communication Module

4 dedicated start bits from the DACS
8 bits dedicated to solar array sub-group
8 bits dedicated to WISPR address identification
8 bits dedicated to a Cyclic Redundancy Code (CRC)
4 stop bits

### Handshake Protocol—Transmitted by WISPR

4 dedicated start bits designated as response from RPVCM identification
8 bits dedicated to identification of solar array sub-group
8 bits dedicated to WISPR address identification
8 bits dedicated to a Cyclic Redundancy Code (CRC)
4 stop bits

### Data Transmission Request Protocol—Transmitted by DACS Communication Module

4 dedicated start bits from the DACS
8 bits dedicated to solar array sub-group
8 bits dedicated to WISPR address identification
2 bits dedicated to initiate data transmission by RVMP
8 bits dedicated to a Cyclic Redundancy Code (CRC)
4 stop bits

### Data Transmission Acknowledgment Protocol—Transmitted by WISPR Module

4 dedicated start bits from the WISPR identification
8 bits dedicated to solar array sub-group
8 bits dedicated to WISPR address identification
2 bits dedicated to data transmission initiation by RVMP
8 bits dedicated to a Cyclic Redundancy Code (CRC)
4 stop bits

### Data Transmission Protocol—Transmitted by WISPR Module

4 dedicated start bits from the WISPR identification
8 bits dedicated to solar array sub-group
8 bits dedicated to WISPR address identification
8 bits for totalized mean current value—2 bit for parameter type and 6 for value
8 bits for totalized mean voltage value—2 bits for parameter and six for value
8 bits dedicated to a Cyclic Redundancy Code (CRC)
4 stop bits

### Data Transmission Termination Protocol—Transmitted by WISPR Module

4 dedicated start bits from the WISPR identification
8 bits dedicated to solar array sub-group
8 bits dedicated to WISPR address identification
2 bits dedicated to data transmission termination from RVMP
8 bits dedicated to a Cyclic Redundancy Code (CRC)
4 stop bits

### Handshake Termination Protocol—Transmitted by DACS Communication Module

4 dedicated start bits from the DACS
8 bits dedicated to solar array sub-group
8 bits dedicated to WISPR address identification
4 bits confirmation of transmission
8 bits dedicated to a Cyclic Redundancy Code (CRC)
4 stop bits

The above communication cycle may be repeated simultaneously or sequentially for as many WISPR modules are present in the solar power system.

The DACS system may also include a custom protocol for the deactivating or activating the WISPR module. The deactivation of the WISPR module is implemented by a command called the Crowbar CLOSE Protocol which is presented below and may be transmitted from the DACS Communication Module
4 dedicated start bits from the DACS
8 bits dedicated to solar array sub-group
8 bits dedicated to WISPR address identification
4 bits global crowbar SHORT signal broadcast
8 bits dedicated to a Cyclic Redundancy Code (CRC)
4 stop bits

In order to activate the PV modules, the DACS Communication Module transmits a Crowbar open command to the WISPR modules. The command may follow the Crowbar OPEN Protocol, which is disclosed below.
4 dedicated start bits from the DACS
8 bits dedicated to solar array sub-group
8 bits dedicated to WISPR address identification
4 bits global crowbar OPEN signal broadcast
8 bits dedicated to a Cyclic Redundancy Code (CRC)
4 stop bits

The DACS system also allows the real-time acquisition of data from individual WISPR modules. The DACS system also allows the real-time acquisition of meteorological and atmospheric data collected by each WISPR module. The WISPR module may also be configured to have input channels attached to local instruments which can be accessed utilizing the application software in the DACS system. For example, miniature weather stations may measure meteorological and/or atmospheric data and transmit the meteorological and/or atmospheric data to a WISPR module. The WISPR module may then transmit the meteorological and/or atmospheric data to the DACS system. The transmission may be on a scheduled basis or on an as requested basis. The application software in the DACS system may process the acquired output power data and meteorological and/or atmospheric data, and generate reports that present the information (either visually or via a hard copy report). For example, each WISPR module may include analog to digital input channels to receive, from the weather station, the measured meteorological or atmospheric data such as wind direction and speed, outdoor ambient temperature, solar irradiance, humidity and precipitation.

After the results (power output, atmospheric and/or meteorological) have been received by the DACS system and stored in the database (or temporary file) of the DACS computer. The DACS system application software, when executed, may generate information identifying a real-time summary total solar power output from the PV modules being measured. The report may be for a string of PV modules or for the entire solar system of PV modules. The total solar power output report may be displayed as a histogram or bar chart and the output power is measured in kilowatt hours. The DACS system application software may also generate a total accumulated summary total solar power output for an established or set timeframe. Illustratively, the DACS system application software may generate data that identifies the total accumulated solar power output for the last two weeks. The total accumulated solar output power may be measured in kilowatt hours and the report may be displayed as a histogram or bar chart.

The DACS system application software may also generate a real time array string power output for any of the array strings of PV modules. The power output is measured in kilowatt hours.

The DACS system application software, when executed, may also automatically poll a PV module or a PV string (e.g., selected group of PV modules) utilizing the individual address (or addresses) of the WISPR modules corresponding to the PV module (or PV string). The DACS system application software may receive this information and generate historical data for power output for the selected PV module or PV string. The power output may be measured in kilowatt hours. In addition, the DACS system application software may receive the power information for the selected PV module or PV string and generate time differentiated output power readings. In other words, the received power output readings may be for different times. This information may then be compared to the received power output readings. This results in the DACS system application software generating comparative data that identifies comparative performance of the selected PV module or the PV string of PV modules. The comparative data may then be displayed in reports.

In addition, an atmospheric and/or meteorological condition may also be measured at the PV module and sent to the DACS system. The DACS system application software may receive the atmospheric or meteorological information and generate information identifying output power performance at different meteorological and atmospheric display conditions (such as varying climate conditions). This information may be displayed in reports.

Upon receipt of the output power information from the WISPR modules for the PV modules, the DACS computer may store the output power information and time information as to when the output power was measured The DACS system application software may also generate a time stamped PV module output power report. This report would present the output power for each PV module at a specific time. The output power for this report would be in watt-hours because it is for each PV module.

The DACS system may also, on an as requested basis, request power output information and meteorological information from each WISPR module or a string of WISPR modules. The DACS application software, when executed, may receive this information and generate comparative information for the power output or meteorological/atmospheric output form the individual WISPR modules. The DACS application software may display this information so that the information for each of the individual WISPR modules is compared (presented) against each other. Further, PV modules which are in environments with the same atmospheric or meteorlogical conditions may be compared against each other. The data can be utilized to evaluate individual PV module solar power performance and potentially identify PV modules for maintenance.

The DACS system may also, on an as requested basis, request power output information for each WISPR module for a specified time frame. The DACS system application software may then generate historical power output information for the specified timeframe for 1) individual WISPR modules; 2) a string of WISPR modules and 3) an entire solar power system's WISPR modules.

The DACS system application software may also generate maintenance data display reports, solar power systems co-generation efficiency reports and general environmental public information reports.

The maintenance data display reports may include reports which identify when the PV modules are not operating at an acceptable level, e.g., not providing the necessary power output. For example, the reports could be run where the global power system has a differential setpoint limit for performance of PV modules and the report may identify if there was degradation under predetermined environmental conditions. In an embodiment of the invention, the DACS system application software, when executed, may receive power output measurements for one PV module or a plurality of PV modules. A power output setpoint for each PV module may be established and stored in the database. The DACS system application software may compare the power output for the PV module or a plurality of PV modules against the power output setpoint and may place an indicator in a record in the database if the power output of the PV module or plurality of PV modules does not exceed the setpoint. The DACS system application software, when executed, may generate a report identifying PV modules that do not exceed the setpoint. In an embodiment of the invention, the DACS system application software may place an indicator corresponding to a band, i.e., a warning stage band, an alarm stage band, or a failure stage band. The report could identify if the global solar power system was at a Warning Notice stage, an Alarm Notice stage, or a Failure Notice stage.
Similarly, the DACS system application software, when initiated, could generate whether the PV string power level output had a differential setpoint limit and if the PV string power level performance degraded under predetermined environmental conditions. The report, generated based on the results, could identify the condition, such as Warning Notice, Alarm Notice, or Failure Notice
Similarly, the DACS system application software, when executed, may collect measurements for the WISPR power output level and also receive corresponding time, atmospheric or meteorological conditions. The DACS system application software may then identify (by an indicator) if the PV Module power level output had degraded by comparing the PV module output to the power output setpoint. The DACS system application software may then generate a report which displays, for each PV module, whether power degredation had occurred under predetermined environmental conditions. Illustratively, the DACS system may display the PV modules power output (as well as meteorological and/or atmospheric conditions) over time to see if environmental or atmospheric conditions had changed. The indicator may identify if the PV module is in a warning notice stage, an alarm stage, or a failure stage.

The DACS system application software, when initiated, may also generate a report that provides maintenance procedure instructions for the entire solar power system and sub-system components. The DACS system application software may also generate information for the scheduled maintenance of each PV module (including PV module washdown) and other subcomponents of the solar power system. The DACS system application software may also generate information regarding the last maintenance date of each PV module and other subcomponents of the solar power system.

The DACS system application software, when initiated, may also provide a schedule of maintenance for the solar power system components. In addition, it can provide pertinent specification, manufacturer or integrator contact information for each of the solar power system components, including the PV modules and the WISPR modules.

The DACS system application software, when executed, may also calculate a cost of energy conserved by solar power according to an embodiment of the invention. The DACS computer database may include rates for solar energy production during different times of the day, e.g., PEAK rate, MID PEAK rate, and LOW PEAK rate. The DACS computer database may also include regular (non-solar) rates for energy production during different times of the day, (e.g., many municipalities charge different electricity rates during the different times of the day in order to encourage lower use of electricity during the PEAK time periods, such as 7 AM-4 PM). The DACS system application software may use the regular electricity rate information in the database and the power output information from the plurality of PV modules to generate cumulative historical energy conserved information. The DACS system application software, when executed, may generate a report displaying the energy conserved information for a specified timeframe. The DACS system application software may use the solar electricity rate information in the database and the power output information from the plurality of PV modules to generate cumulative historical energy information. The DACS system application software may generate a report displaying the solar energy produced during different specified timeframes. The DACS system application software may also provide a real time display of the solar power system production cost at preset intervals (such as minutes or hours).

The DACS system application software, when initiated, can also take the power output information from the PV modules and calculate pollution abatement statistics. For example, for each kilowatt of electrical power produced by an electrical power generation system, pollutants such as CO2, NOX and other pollutants are generated. Illustratively, a coal fired electrical plant produces 1.4 pounds of CO2 and a natural gas fired electrical plan produces 0.8 pounds of CO2. Accordingly, the database in the DACS system application software may also store amounts of pollutants generated by different fossil fuel energy systems. The DACS system application software can then calculate the pollution abatement statistics, e.g., how much CO2 was not generated, by utilizing the power output from the plurality of PV modules in a solar power system and multiplying it by the average pollutant generated for each kilowatt of energy produced. The DACS systems may display the pollution abatement statistics in a report.

Further, because the DACS system application software has identified an amount of pollution abated by the plurality of PV modules or solar farm system, this may be directly correlated with other pollution abatement measures, e.g., less car miles driven, how many equivalent vehicle emissions have been eliminated, acres of trees not cut down, acres of trees planted, etc. A report presenting these pollution abatement figures and correlated measures may also be generated and then displayed or printed.

Some or all aspects of the invention may be implemented in hardware or software, or a combination of both (e.g., programmable logic arrays). Unless otherwise specified, the algorithms included as part of the invention are not inherently related to any particular computer or other apparatus. In particular, various general purpose machines may be used with programs written in accordance with the teachings herein, or it may be more convenient to construct more specialized apparatus (e.g., integrated circuits) to perform particular functions. Thus, the invention may be implemented in one or more computer programs executing on one or more programmable computer systems each comprising at least one processor, at least one data storage system (which may include volatile and non-volatile memory and/or storage elements), at least one input device or port, and at least one output device or port. Program code is applied to input data to perform the functions described herein and generate output information. The output information is applied to one or more output devices, in known fashion.

Each such program may be implemented in any desired computer language (including machine, assembly, or high level procedural, logical, or object oriented programming languages) to communicate with a computer system. In any case, the language may be a compiled or interpreted language.

Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system may also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention. For example, some of the steps described above may be order independent, and thus can be performed in an order different from that described. Accordingly, other embodiments are within the scope of the following claims.

What is claimed is:

1. A computer implemented method of deactivating a plurality of photovoltaic (PV) modules, comprising:
receiving an alarm condition from a monitoring system; and
transmitting a global shutdown command to a plurality of wireless intelligent solar power reader (WISPR) modules corresponding to the plurality of photovoltaic (PV) modules in response to receiving the alarm condition.

2. The computer-implemented method of claim 1, wherein the global shutdown command causes the plurality of wireless intelligent solar power reader (WISPR) modules to close and latch a relay that shorts a power output for each of the plurality of the photovoltaic (PV) modules.

3. The computer-implemented method of claim 1, further including receiving a mitigation condition and transmitting a global reactivation command to the plurality of WISPR modules corresponding to the plurality of PV modules in response to the mitigation condition.

4. The computer-implemented method of claim 3, wherein the plurality of PV modules is reactivated by opening the crowbar relay on each of the plurality of WISPR modules corresponding to the plurality of PV modules.

5. The computer-implemented method of claim 1, wherein an auxiliary interface receives the alarm condition from the monitoring system, transfers the alarm condition to a data analysis and control (DACS) computer and the DACS computer generates the global shutdown command in response thereto.

6. A computer-implemented method of deactivating a selected group of a plurality of photovoltaic (PV) modules, comprising:
receiving a request to deactivate the selected group of the plurality of PV modules;
utilizing a database to identify addresses of a plurality of wireless intelligent solar power reader (WISPR) modules corresponding to the selected group of the plurality of PV modules;
generating a deactivation command; and
transmitting a command to the plurality of WISPR modules corresponding to the selected group of the plurality of the PV modules to shutdown or deactivate the selected group of the plurality of the PV modules.

7. A computer-implemented method of monitoring a plurality of photovoltaic (PV) modules, comprising:
generating a request to a plurality of WISPR modules for output power readings at the corresponding plurality of PV modules;
receiving the output power reading for each of the corresponding plurality of PV modules at a data acquisition and control system (DACS); and
calculating output power statistics for each of the corresponding plurality of PV modules.

8. The computer-implement method of claim 7, further including generating a total solar power output for the all of the corresponding plurality of PV modules and displaying the total solar power output.

9. The computer-implemented method of claim 7, wherein a set number of PV modules are identified as a PV string and the plurality of PV modules are divided into a plurality of PV strings, further including generating a real time power output for each PV string and displaying the real time power output for each PV string.

10. The computer-implemented method of claim 7, further including initially polling, at set time intervals, each of the plurality of WISPR modules to request the output power for each of the plurality of the PV modules and generating comparative performance statistics for each of the plurality of PV modules.

11. The method of claim 7, further including receiving meteorological information at the plurality of WISPR modules from at least one weather instrument located in proximity of the plurality of WISPR modules.

12. The method of claim 11, further including transmitting the measured meteorological information to a data acquisition and control (DACS) system.

13. A computer-implemented method of operating a wireless intelligent solar power reader (WISPR) module, comprising:
receiving a command from an external device, the command requesting an output power reading from a photovoltaic (PV) module;
transmitting an output power request to the PV module;
receiving an output power reading from the PV module; and
transmitting the output power reading to the external device.

14. The computer-implemented method of claim 13, wherein the command also requests meteorological information from the WISPR module, the WISPR module transmits a meteorological information request to a weather instrument, and the WISPR module receives meteorological information from the weather instrument, which is located in proximity to the WISPR module.

15. The computer-implemented method of claim 14, wherein the transmits the received meteorological information to the external device.

16. A computer-implemented method of operating a wireless intelligent solar power reader (WISPR) module, comprising:
receiving a command from an external device, the command requesting shutdown of the photovoltaic (PV) module; and
generating a command to close and latch a relay that shorts a power output of the PV module.

17. The computer-implemented method of claim 16, further including:
receiving an activation command from the external device, the activation command requesting reactivation of the photovoltaic module; and
generating a command to open the relay and allow power to be output from the photovoltaic module.
